(19) United States
(12) Patent Application Publication
(10) Pub. No.: US 2014/0290859 A1
(43) Pub. Date: Oct. 2, 2014

(54) WET ETCHING APPARATUS

(71) Applicant: SHIBAURA MECHATRONICS CORPORATION, Yokohama-shi (JP)

(72) Inventors: Nobuo KOBAYASHI, Yokohama-shi (JP); Yoshiaki KUROKAWA, Yokohama-shi (JP); Koichi HAMADA, Yokohama-shi (JP)

(73) Assignee: SHIBAURA MECHATRONICS CORPORATION, Yokohama-shi (JP)

(21) Appl. No.: 14/228,515

(22) Filed: Mar. 28, 2014

(30) Foreign Application Priority Data
Mar. 29, 2013 (JP) 2013-073721
Mar. 7, 2014 (JP) 2014-045275

(51) Int. Cl. H01L 21/67

(52) U.S. Cl. CPC H01L 21/67075
USPC 156/345.15

(57) ABSTRACT

A wet etching apparatus comprises a reservoir unit for storing aqueous solution of phosphoric acid, an additive reservoir unit for storing a silica additive; a concentration detecting unit configured to detect the silica concentration in the aqueous solution of phosphoric acid stored in the reservoir unit; a control unit configured to supply the silica additive from the additive reservoir unit to the reservoir unit if the silica concentration in the aqueous solution of phosphoric acid, detected by the concentration detecting unit, is lower than a prescribed value; and a processing unit configured to process the substrate with the aqueous solution of phosphoric acid stored in the reservoir unit.

### CROSS-REFERENCE TO RELATED APPLICATIONS

This application is based upon and claims the benefit of priority from the prior Japanese Patent Application No. 2013-073721, filed Mar. 29, 2013, No. 2014-045275, filed Mar. 7, 2014 the entire contents of which are incorporated herein by reference.

### BACKGROUND OF THE INVENTION

1. Field of the Invention

This invention relates to a wet etching apparatus which etches the surface of a substrate such as a semiconductor wafer by using an etchant.

2. Description of the Related Art

The wet etching apparatus is a substrate-processing apparatus for use in the steps of manufacturing electronic apparatuses such as semiconductor devices and liquid crystal displays. (Refer to, for example, Jpn. Pat. Appln. KOKAI Publication No. 2002-336761). The wet etching apparatus performs selective etching for nitride film and oxide film formed on a semiconductor substrate, that is, etches nitride film more than oxide film.

In the steps of manufacturing a semiconductor device, a nitride film (e.g., SiN film) and an oxide film (e.g., SiO₂ film), used as an etching stop film, are formed one on the other, on a semiconductor substrate. An etching solution, such as an aqueous solution of phosphoric acid (H₃PO₄), is used, for processing the nitride film and oxide film. The more the semiconductor device is miniaturized, the thinner these films will become. Therefore, the etching selection of any film to be etched to the etching stop film must therefore be increased. If the etching selection is not sufficiently high, no etching stop film will exists in the etching step. This is problematical to the manufacture of the semiconductor device.

The nitride film is etched by using a hot aqueous solution of phosphoric acid. However, the aqueous solution of phosphoric acid exhibits a low etching selection for the nitride film with respect to the etching stop film. As is known, the etching selection of the nitride film with respect to the etching stop film will increase if the silica concentration is raised in the aqueous solution of phosphoric acid. Therefore, silica may be added to the aqueous solution of phosphoric acid. In this case, however, the aqueous solution will be vaporized as the aqueous solution is continuously processed, inevitably raising the silica concentration. Consequently, solid silica will precipitate on the semiconductor device in some cases. The solid silica results in contamination, impairing the quality control during the process. Conversely, if the silica concentration is low, a sufficiently high etching selection cannot be attained during the process.

FIG. 5 is a diagram showing the relation the amount of TEOS solution added has with the etching selection ratio SiN/SiO₂. FIG. 6 is a diagram showing the relation the amount of TEOS solution added and the amount of SiO₂ added has with the etching selection ratio SiN/SiO₂. As seen from FIG. 5 and FIG. 6, the etching rate of the oxide film depends on the TEOS (tetraethyl orthosilicate) concentration in the etching solution. A method of increasing the silica concentration in the etching solution is known, in which a SiN dummy film, solid powder or TEOS is dissolved in the solution, thereby increasing the amount of silica (silicic acid).

A solution of silicic acid or ethyl silicate, for example, is added, in a prescribed amount, to the aqueous solution used. More specifically, about 1000 ppm of an additive (i.e., ethyl polysilicate or TEOS) is added to 75% phosphoric acid. Then, the etching rate of the SiO₂ film can be controlled while maintaining the etching rate of the SiN film. In order to set the etching rate of the SiO₂ film to a desirable value, the amount of the additive used is changed.

In a method wherein a SiN dummy film is introduced to an aqueous solution of phosphoric acid, thereby dissolving silica in the aqueous solution, it is necessary to control the amount of silica dissolved, in accordance with time taken to process the dummy film and the number of substrates being processed. Stable control of the amount of silica dissolved (i.e., silica concentration in the solution) is, however, difficult to accomplish. That is, it is difficult to control the amount of silica dissolved in the solution.

### BRIEF SUMMARY OF THE INVENTION

An object of this invention is to provide a wet etching apparatus, wherein the concentration of silica dissolved can easily be controlled appropriately.

The apparatus comprises a reservoir unit configured to store aqueous solution of phosphoric acid, an additive reservoir unit configured to store a silica additive; a concentration detecting unit configured to detect the silica concentration in the aqueous solution of phosphoric acid stored in the reservoir unit; an additive supplying unit configured to supply the silica additive from the additive reservoir unit to the reservoir unit if the silica concentration in the aqueous solution of phosphoric acid, detected by the concentration detecting unit, is lower than a prescribed value; and a processing unit configured to process the substrate with the aqueous solution of phosphoric acid stored in the reservoir unit.

The etching apparatus can therefore perform wet etching, while appropriately controlling the silica concentration.

### BRIEF DESCRIPTION OF THE SEVERAL VIEWS OF THE DRAWING

FIG. 1 is a diagram showing a wet etching apparatus according to a first embodiment of this invention;

FIG. 2 is a diagram showing the relation the amount of colloidal silica added has with the etching rate of SiO₂ in the wet etching apparatus;

FIG. 3 is a diagram showing the relation the amount of colloidal silica added has with the etching selection ratio SiN/SiO₂ in the wet etching apparatus;

FIG. 4 is a diagram showing a wet etching apparatus according to a second embodiment of this invention;

FIG. 5 is a diagram showing the relation the amount of TEOS solution added has with the etching selection ratio SiN/SiO₂; and

FIG. 6 is a diagram showing the relation the amounts of TEOS solution and SiO₂ added have with the etching selection ratio SiN/SiO₂.

### DETAILED DESCRIPTION OF THE INVENTION

An embodiment of this invention will be described, with reference to the accompanying drawing.

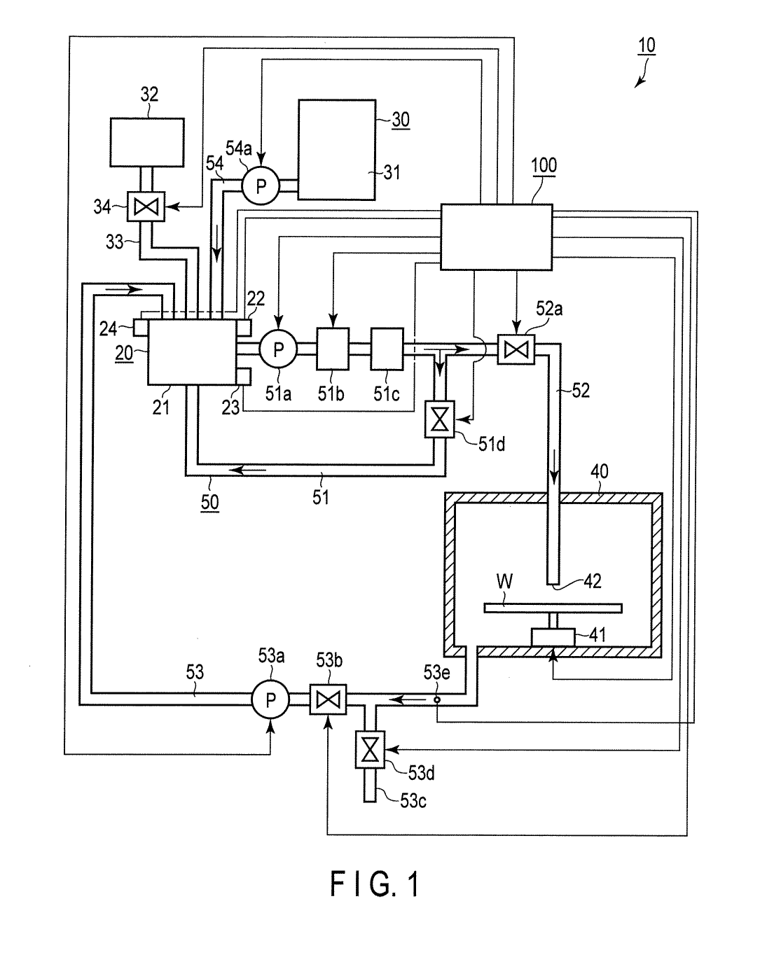

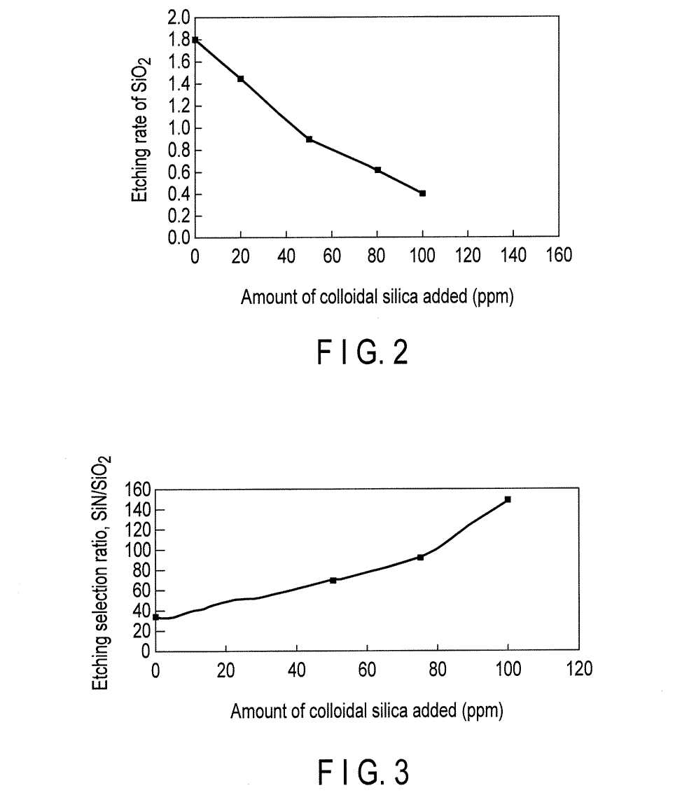

FIG. 1 is a diagram showing a wet etching apparatus 10 according to an first embodiment of this invention. FIG. 2 is a diagram showing the relation the amount of colloidal silica added has with the etching rate of SiO₂ in the wet etching apparatus. FIG. 3 is a diagram showing the relation the amount of colloidal silica added has with the etching selection ratio SiN/SiO₂ in the wet etching apparatus 10.

In FIG. 1, W is a substrate, such as a semiconductor wafer, which is subjected to wet etching. On the surface of the substrate W, a nitride film (e.g., SiN film) and an oxide film (e.g., SiO2 film), used as an etching stop film, are formed one on the other.

As shown in FIG. 1, the wet etching apparatus 10 comprises a reservoir unit 20 for storing an aqueous solution of phosphoric acid, an additive reservoir unit 30 for a storing silica additive, a processing unit 40 configured to perform wet etching on the substrate W, a circulation unit 50 connecting the units 20, 30 and 40, and a control unit 100 configured to control the units 20, 30, 40 and 50 in unison.

The reservoir unit 20 comprises a tank 21 for storing the aqueous solution of phosphoric acid, having a prescribed silica concentration, a concentration detecting unit 22 provided in the tank 21 and configured to detect the silica concentration in the aqueous solution of phosphoric acid, and a temperature detecting unit 23 configured to detect the temperature of the aqueous solution of phosphoric acid in the tank 21. The tank 21 opens at the top, stores the aqueous solution of phosphoric acid and is connected to a solution replenishing unit 32 by a solution replenishing pipe 33. Fresh aqueous solution of phosphoric acid is supplied from the solution replenishing unit 32 to the tank 21 through a valve 34 provided on the solution replenishing pipe 33. The tank 21 is made of a material such as fluorine-based resin or quartz. The concentration detecting unit 22 and the temperature detecting unit 23 are connected to the control unit 100. Signals representing the concentration of silica and temperature of the aqueous solution of phosphoric acid, so detected, are output to the control unit 100. To the tank 21, a circulation pipe 51, a recovery pipe 53 and an additive pipe 54 are connected. The pipes 51, 53 and 54 will be described later.

The additive reservoir unit 30 comprises an additive tank 31 for storing an additive. To the additive tank 31, the additive pipe 54 is connected. The additive stored in the additive tank 31 is, for example, liquid colloidal silica for use in an abrasive.

The processing unit 40 has the function of etching the selected parts of the nitride film formed on the surface of the substrate W, thereby to remove these parts of the nitride film, by using an aqueous solution of phosphoric acid, with a prescribed silica concentration. The processing unit 40 comprises a rotation mechanism 41 configured to rotate the substrate W, and a nozzle 42 configured to apply the aqueous solution having the prescribed silica concentration to the substrate W rotated by the rotation mechanism 41. The nozzle 42 is provided at one end of a solution applying pipe 52. The aqueous solution of phosphoric acid, having the prescribed silica concentration, is thus applied as processing liquid from the nozzle 42. That is, the processing unit 40 applies the aqueous solution of phosphoric acid, having the prescribed silica concentration, through the nozzle 42 to the surface of the rotating substrate W, thereby removing the selected parts of the nitride film. The nozzle 42 is mounted on an arm member (not shown), and may thereby be swung above the surface of the substrate W.

The circulation unit 50 comprises a circulation pipe 51, an outlet pipe 52, a recovery pipe 53, and an additive pipe 54. The circulation pipe 51 is connected to the tank 21. The outlet pipe 52 is connected to the circulation pipe 51 to supply the aqueous solution of phosphoric acid, which has the prescribed silica concentration. The recovery pipe 53 (recovery unit) is provided to supply the aqueous solution after use in the process, back to the tank 21. The additive pipe 54 extends from the additive tank 31 and is connected to the tank 21.

On the circulation pipe Si, a pump 51a, a heater 51b, a filter 51c, and a valve 51d are provided. The pump 51a circulates the aqueous solution in the circulation pipe 51. The heater 51b heats the aqueous solution of phosphoric acid, which is flowing in the circulation pipe 51. The filter 51c filters out foreign matter from the aqueous solution flowing in the circulation pipe Si. The valve 51d is configured to open and close the circulation pipe 51.

The pump 51a is electrically connected to the control unit 100. Controlled by the control unit 100, the pump 51a forces the aqueous solution of phosphoric acid into the circulation pipe Si. The heater 51b is electrically connected to the control unit 100. Controlled by the control unit 100, the heater 51b heats the solution flowing in the circulation pipe 51. The valve 51d is electrically connected to the control unit 100 and is opened or closed under control by the control unit 100. In this embodiment, the valve 51d remains opened while the wet etching apparatus 10 is operating in normal state.

The outlet pipe 52 extends from a position between the filter 51c and the valve 51d, both of which are provided on the circulation pipe 51, and is used to apply the aqueous solution of phosphoric acid, having a prescribed silica concentration, to the substrate W. The distal end of the outlet pipe 52 is therefore directed to the surface of the substrate W. On the outlet pipe 52, a valve 52a is mounted, to open and close the outlet pipe 52. The valve 52a is electrically connected to the control unit 100 and is opened or closed under control by the control unit 100. On receiving the instruction for starting the application of the aqueous solution, the control unit 100 opens valve 52a provided on the outlet pipe 52, supplying the aqueous solution of phosphoric acid, which has the prescribed silica concentration, from the circulation pipe 51 to the outlet pipe 52, if the silica concentration of the aqueous solution of phosphoric acid in the tank 21, detected by the concentration detecting unit 22, has reached the value preset in the control unit 100 and if the aqueous solution of phosphoric acid in the tank 21 has the temperature preset in the control unit 100.

The recovery pipe 53 connects the tank 21 to the processing unit 40. On the recovery pipe 53, a pump 53 and a valve 53b are provided. The pump 53a causes the aqueous solution to flow in the recovery pipe 53. The valve 53b is configured to open and close the recovery pipe 53. The pump 53a is electrically connected to the control unit 100. Controlled by the control unit 100, the pump 53a forces the aqueous solution after use in the process, into the recovery pipe 53. In this embodiment, the pump 53a is kept driven while the wet etching apparatus 10 is operating in normal state. The valve 53b is electrically connected to the control unit 100. Controlled by the control unit 100, the valve 53b is opened or closed. An outlet pipe 53c is connected to the recovery pipe 53, at a position upstream the valve 53b. Further, a valve 53d is provided on the outlet pipe 53c, to open and close the outlet pipe 53c. The valve 53d is electrically connected to the control unit 100. Controlled by the control unit 100, the valve 53d opens or closes the outlet pipe 53c. In that part of the recovery pipe 53, which extends between the processing unit 40 and the valve 53b, a concentration sensor 53e is provided to detect the silica concentration in the solution flowing in the recovery pipe 53. The output of the concentration sensor 53e is input to the control unit 100.

The additive pipe 54 connects the additive tank 31 to the tank 21. On the additive pipe 54, a pump 54a is provided, which constitutes an additive supplying unit. The pump 54a is electrically connected to the control unit 100. Controlled by the control unit 100, the pump 54a forces colloidal silica out of the additive tank 31, into the additive pipe 54.

The control unit 100 comprises a microcomputer and a storage unit. The microcomputer is designed to control some of other components of the wet etching apparatus 10. The storage unit stores various process information and various programs, all concerning the wet etching. The control unit 100 supplies the silica additive from the additive tank 31 to the tank 21 in accordance with the above-mentioned various process information and various programs, thereby adjusting the silica concentration of the aqueous solution of phosphoric acid to the prescribed value if the silica concentration detected by the concentration detecting unit 22 is lower than the prescribed value set in the control unit 100. Thus, the control unit 100 has the function of an additive supplying unit.

In the wet etching apparatus 10 configured as described above, the wet etching is performed as will be described below, under control by the control unit 100. First, the solution replenishing unit 32 supplies a prescribed amount of the aqueous solution of phosphoric acid, which is stored in the tank 21. The valve 51d remains opened, but the valve 52a is closed. Then, the pump 51a and the heater 51b are activated. Once the pump 51a has been activated, the aqueous solution of phosphoric acid in the tank 21 circulates in the circulation pipe 51. While the aqueous solution is circulating in the circulation pipe 51, the filter 51c remove the foreign matter from the aqueous solution of phosphoric acid, and the heater 51b heats the aqueous solution of phosphoric acid. The temperature of the aqueous solution of phosphoric acid in the tank 21 is detected by the temperature detecting unit 23. The silica concentration of the aqueous solution of phosphoric acid in the tank 21 is detected by the concentration detecting unit 22.

The control unit 100 controls the heater 51b in accordance with the output of the temperature detecting unit 23, thereby heating the aqueous solution to the predetermined temperature (160 to 170° C.) and maintaining the aqueous solution at the predetermined temperature.

If the silica concentration of the aqueous solution of phosphoric acid in the tank 21, detected by the concentration detecting unit 22, is lower than the prescribed value, the pump 54a is driven, introducing the colloidal silica used as an additive, from the additive tank 31 to the tank 21 until the silica concentration in the aqueous solution increases to the prescribed value. Since the colloidal silica introduced into the tank 21 circulates in the circulation pipe 51, together with the aqueous solution in the tank 21, it is uniformly mixed with the aqueous solution of phosphoric acid.

After the aqueous solution of phosphoric acid has been supplied to the tank 21, the silica concentration is continuously detected. The aqueous solution is maintained at the predetermined temperature. If the colloidal silica is added in an amount very small with respect to the amount of the aqueous solution stored in the tank 21, it is unnecessary to consider the decrease in the temperature of the aqueous solution of phosphoric acid, resulting from the addition of colloidal silica.

Then, the substrate W is arranged in the processing unit 40. On receiving the instruction for starting the application of the aqueous solution of phosphoric acid, the control unit 100 opens the valve 52a, while keeping the valve 51d open (thus circulating the solution), if the silica concentration in the aqueous solution stored in the tank 21 has the prescribed concentration and has the predetermined temperature. As a result, the aqueous solution of phosphoric acid, stored in the tank 21, is applied from the nozzle 42 to the substrate W, performing a wet etching process.

The nitride film and oxide film formed on the substrate W are processed with the process solution applied to the substrate W.

The process solution applied to the substrate W is an aqueous solution of phosphoric acid having the prescribed silica concentration. The wet etching therefore proceeds at a desirable selection ratio. The etching stop film is therefore not completely removed, causing no problems to the manufacture of the semiconductor device, even if the device is composed of very small elements. FIG. 2 shows the relation the amount of colloidal silica added has with the etching rate of SiO₂. FIG. 3 is a diagram showing the relation the amount of colloidal silica added has with the etching selection ratio SiN/SiO₂.

The process solution flowing from the surface of the substrate W to the bottom of the processing unit 40 flows into the recovery pipe 53 connected to the bottom of the processing unit 40, and is recovered in the tank 21 as the pump 53a is driven. At this point, the valve 53b is opened and the valve 53d is closed. If the nitride film is etched away from a plurality of substrates W, the silica concentration detected by the concentration sensor 53e may exceed a prescribed range preset by the control unit 100. In this case, the process solution will be discharged through the outlet pipe 53c, and not recovered into the tank 21. Then, the valve 53b is closed and the valve 53d is opened. A heater may be provided on the recovery pipe 53, in order to heat the process liquid being recovered into the tank 21 through the recovery pipe 53.

When the etching process performed on the substrate W ends, the control unit 100 closes the valve 52a. When the substrate W is replaced by a new substrate W in the processing unit 40, the control unit 100 opens the valve 52a again, whereby the above-mentioned etching process is performed on the new substrate W.

As the etching process is repeated, each time on one substrate W, the aqueous solution of phosphoric acid, stored in the tank 21, is consumed. Thus, it is desirable that a liquid-level meter 24 should be provided on the tank 21 as shown in FIG. 1, in order to control the surface level of the aqueous solution in the tank 21 as will be explained below.

The liquid-level meter 24 is connected to the control unit 100 and configured to detect the surface level of the aqueous solution of phosphoric acid, stored in the tank 21, and generates a signal representing the surface level so detected. The signal is output to the control unit 100. The control unit 100 closes the valve 52a if the signal shows that the surface of the aqueous solution lowers below the level preset in the control unit 100. The surface of the aqueous solution in the tank 21 may be detected below the level preset in the control unit 100 during the etching process performing on the substrate W, the valve 52a is closed when the etching process is completed. The substrate W can therefore be etched uniformly.

Next, the control unit 100 supplies the aqueous solution of phosphoric acid from the solution replenishing unit 32 to the tank 21 until the surface of the aqueous solution in the tank 21 rises to the level preset by the control unit 100. At this point, the pump 51a has been activated. The aqueous solution of phosphoric acid therefore circulates in the circulation pipe 51. Further, the control unit 100 controls the heater 51b, causing the same to heat the aqueous solution in the tank 21 to the predetermined temperature. As the aqueous solution of phosphoric acid is supplied to the tank 21, the silica concentration in the tank 21 decreases. If the silica concentration detected by the concentration detecting unit 22 is found below the value preset in the control unit 100, the control unit 100 drives the pump 54a, introducing the colloidal silica from the additive tank 31 into the tank 21, and increasing the silica concentration in the tank 21 to the prescribed value.

Assume that the solution replenishing unit 32 thus supplies fresh aqueous solution of phosphoric acid from to the tank 21 and the silica concentration in the aqueous solution, detected by the concentration detecting unit 22, has the preset value, and that that the aqueous solution has the predetermined temperature. Then, the process on the substrate S is started. More precisely, in accordance with the instruction for staring the application of the aqueous solution of phosphoric acid, the control unit 100 opens the valve 52a. The aqueous solution of phosphoric acid is thereby applied through the nozzle 42 to the new substrate W, and the wet etching is performed.

As the aqueous solution of phosphoric acid is recovered from the processing unit 40 back into the tank 21 through the recovery pipe 53, the concentration of the aqueous solution of phosphoric acid, stored in the tank 21, may decrease below the value preset in the control unit 100. In this case, the control unit 100 closes the valve 52a when the concentration detecting unit 22 detects this concentration decrease. If the control unit 100 detects a decrease in the concentration of the aqueous solution in the tank 21 during the etching process being performed on the substrate W, it closes the valve 52a when the etching process is completed. The substrate W can therefore be uniformly etched.

The control unit 100 then activates the pump 54a, introducing the colloidal silica from the tank 31 into the tank 21, until the silica concentration of the aqueous solution in the tank 21 increases to the prescribed value. The colloidal silica introduced into the tank 21 circulates in the circulation pipe 51, together with the aqueous solution of phosphoric acid. The colloidal silica is therefore mixed uniformly with the aqueous solution of phosphoric acid. Further, the temperature of the aqueous solution of phosphoric acid is controlled to the predetermined temperature.

Thus, if a decrease of the silica concentration is detected in the aqueous solution of phosphoric acid in the tank 21 while the substrate W is being processed, the control unit 100 controls some components to perform the etching process on the substrate W if the aqueous solution of phosphoric acid in the tank 21 has the prescribed silica concentration and the predetermined temperature, as in the case where fresh aqueous solution of phosphoric acid is supplied from the solution replenishing unit 32 to the tank 21. More precisely, the control unit 100 opens the valve 52a in response to the instruction for starting the application of the aqueous solution of phosphoric acid. The aqueous solution of phosphoric acid is applied from the tank 21 through the nozzle 42 to the substrate W, and the wet etching process is performed.

As described above, this embodiment can adjust the silica concentration of the aqueous solution stored in the tank 21, to an appropriate value. Thus, the silica concentration of the aqueous solution of phosphoric acid can be easily controlled to an appropriate value.

The appropriate control of the silica concentration in the aqueous solution of phosphoric acid can prevent the silica concentration from rising above the preset value, ultimately preventing solid silica from precipitating on the semiconductor device. Moreover, the appropriate control of the silica concentration can prevent the silica concentration from lowering below the preset value, ultimately avoiding the failure in obtaining a prescribed etching selection ratio. In short, the silica concentration in the aqueous solution of phosphoric acid is adjusted, controlling the etching rates of the nitride film and oxide film, within a desirable range, whereby a stable etching process can be performed. As a result, a sufficient etching selection ratio is attained. This prevents the problem with the manufacturing of semiconductor devices, and helps to enhance the product quality.

Moreover, colloidal silica, which contains no alcohol, excels in safety, and can be readily dissolved. In view of this, the silica concentration is easy to control in the aqueous solution of phosphoric acid.

In the embodiment described above, substrates W are processed one by one. The process is not limited to this scheme, nevertheless. The substrates may be processed in, for example, a batch processing scheme, wherein a plurality of substrates W are immersed in the processing tank at the same time. Moreover, the silica used is not limited to colloidal silica. Any other silica that is soluble in the aqueous solution of phosphoric acid can be used in the invention. Furthermore, a silica supplying pipe may be connected to the pipe supplying the aqueous solution of phosphoric acid.

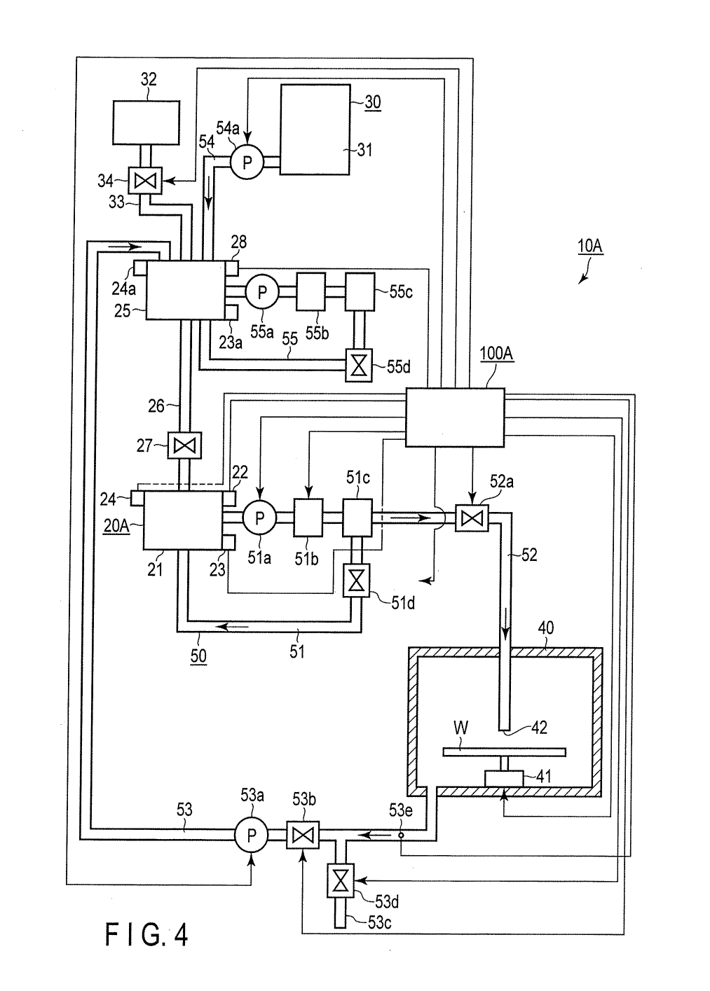

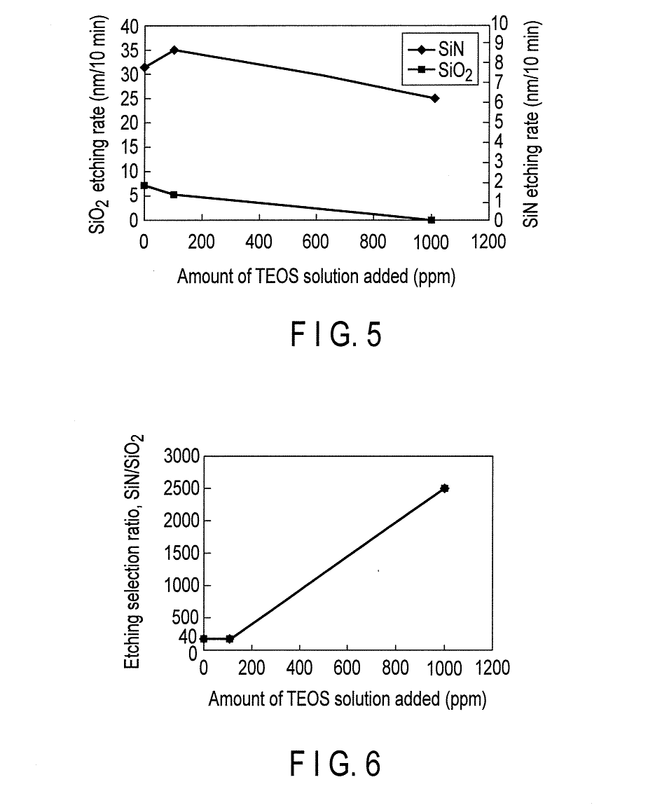

FIG. 4 is a diagram showing a wet etching apparatus according to a second embodiment of this invention. The components shown in FIG. 4 and identical to those shown in FIG. 1 are designated by the same reference numerals, and will not be described in detail.

As shown in FIG. 4, the wet etching apparatus 10A comprises a reservoir unit 20A for storing an aqueous solution of phosphoric acid, an additive reservoir unit 30 for a storing silica additive, a processing unit 40 configured to perform wet etching on the substrate, a circulation unit 50 connecting the units 20A, 30 and 40, and a control unit 100A configured to control the units 20A, 30, 40 and 50 in unison.

The reservoir unit 20A comprises a tank 21 for storing the aqueous solution of phosphoric acid, having a prescribed silica concentration, a concentration detecting unit 22 provided in the tank 21 and configured to detect the silica concentration in the aqueous solution of phosphoric acid, and a temperature detecting unit 23 configured to detect the temperature of the aqueous solution of phosphoric acid in the tank 21, a liquid-level meter 24a, and a sub-tank 25. The tank 21 opens at the top, stores the aqueous solution of phosphoric acid and is connected to the sub-tank 25 by a tank pipe 26. From the sub tank 25, the aqueous solution of phosphoric acid, mixed with colloidal silica, is supplied trough a valve 27.

A fresh solution supplying pipe 33, a recovery pipe 53, and an additive pipe 54 are connected to the upstream part of the sub-tank 25. The fresh solution supplying pipe 33 is connected, at the other end, to a solution replenishing unit 32. A valve 34 is provided on the fresh solution supplying pipe 33. The tank 21 is connected to the downstream part of the sub-tank 25 by a tank pipe 26. A concentration detecting unit 28, a temperature detecting unit 23a and the liquid-level meter 24a are provided on the sub-tank 25. The outputs of the detecting units 28 and 23a and the output of the liquid-level meter 24a are transmitted to the control unit 100A. The concentration detecting unit 28, temperature detecting unit 23a and liquid-level meter 24a are identical to those of the concentration detecting unit 22, temperature detecting unit 23 and liquid-level meter 24 used in the first embodiment.

To the sub-tank 25, a circulation pipe 55, which is equivalent to the circulation pipe 51, is connected. On the circulation pipe 55, a pump 55a, a heater 55b, a filter 55c, and a valve 55d are provided. The pump 55a circulates an aqueous solution of phosphoric acid when it is driven. The heater 55b heats the solution flowing in the circulation pipe 55. The filter 55c filters out foreign matter from the aqueous solution flowing in the circulation pipe 55. The valve 55d is configured to open and close the circulation pipe 55. The pump 55a, heater 55b and valve 55d are electrically connected to the control unit 100A. The pump 55a, heater 55b and filer 55c are equivalent to the pump 51a, heater 51b and filter 51c, respectively, and will not be described in detail. The heater 55b heats the aqueous solution flowing in the circulation pipe 55. In this embodiment, the pump 55a keeps operating and the valve 55d remains open, while the wet etching apparatus 10A is operating in normal state.

The valve 34 provided on the fresh solution supplying pipe 33 is electrically connected to the control unit 100A, and is opened or closed under control by the control unit 100A.

The control unit 100A comprises a microcomputer and a storage unit. The microcomputer is designed to control some of other components of the wet etching apparatus 10A. The storage unit stores various process information and various programs. The control unit 100A supplies the silica additive from the additive tank 31 to the sub-tank 25 in accordance with the above-mentioned various process information and various programs, if the silica concentration in the aqueous solution of phosphoric acid, detected by the concentration detecting unit 28, is lower than the value preset in the control unit 100A. Thus, the control unit 100 has the function of an additive supplying unit.

In the wet etching apparatus 10A configured as described above, the wet etching is performed as will be described below, under control by the control unit 100A. First, the solution replenishing unit 32 supplies a prescribed amount of the aqueous solution of phosphoric acid, which is stored in the sub-tank 25, while the valve 27 remains closed. The aqueous solution is treated in the same way as the aqueous solution in the tank 21 is treated in the wet etching apparatus 10. An aqueous solution of phosphoric acid, having the prescribed silica concentration and the predetermined temperature, is thereby prepared in the sub-tank 25.

The process solution flowing from the surface of the substrate W to the bottom of the processing unit 40 flows into the recovery pipe 53 connected to the bottom of the processing unit 40, and is recovered in the sub-tank 25 as the pump 53a is driven. As the aqueous solution of phosphoric acid is recovered in the sub-tank 25, the silica concentration in the sub-tank 25 gradually decreases. When the silica concentration falls below the prescribed value, the concentration is controlled to the predetermined level, as in the first embodiment.

In the preparation step prior to the start of the process, the tank 21 is empty. Almost all aqueous solution of phosphoric acid, prepared in the sub-tank 25 as described above, is therefore supplied to the tank 21 when the valve 27 is opened. The aqueous solution may be so supplied to the tank 21 on condition that the aqueous solution in the sub-tank 25 has the silica concentration and temperature, both preset in the control unit 100A.

The temperature of the aqueous solution of phosphoric acid, supplied to the tank 21 and having the prescribed silica concentration is controlled to the predetermined value and maintained at the prescribed value while it is flowing in the circulation pipe 51. On receiving the instruction for starting the application of the aqueous solution, the control unit 100A opens valve 52a on condition that the aqueous solution in the tank 21 has the silica concentration and the temperature, both preset in the control unit 100A, thereby supplying the aqueous solution of phosphoric acid, which has the prescribed silica concentration, from the circulation pipe 51 to the outlet pipe 52.

In this embodiment, the valve 27 is closed once the aqueous solution of phosphoric acid, having the prescribed silica concentration, has been supplied from the sub-tank 25 to the tank 21. In the sub-tank 25, an aqueous solution having the prescribed silica concentration is prepared as described above in detail.

As the etching process is repeated, each time on a plurality of substrates W, the aqueous solution of phosphoric acid, in the tank 21, is gradually consumed. When the liquid-level meter 24 detects that the aqueous solution has been consumed in a preset amount, the control unit 100A opens the valve 27, and supplies the aqueous solution from the sub-tank 25 to the tank 21, making up for the amount consumed. The aqueous solution so replenished has the prescribed silica concentration, and is thoroughly mixed with the aqueous solution remaining in the tank 21 while it is flowing in the circulation pipe 51. On receiving the instruction for starting the application of the aqueous solution, the control unit 100 A opens valve 52a. As a result, the aqueous solution of phosphoric acid, having the silica concentration controlled to the prescribed value and heated to the predetermined temperature, is applied from the nozzle 42 to the substrate W.

As has been described, the silica concentration of the aqueous solution of phosphoric acid can be adjusted to an appropriate value before it is applied to the substrate in this embodiment as in the wet etching apparatus 10 shown FIG. 1. The silica concentration of the aqueous solution can thus be controlled easily and appropriately. Further, since the sub-tank 25 is provided, in which the aqueous solution of phosphoric acid is mixed with colloidal silica, the aqueous solution to be used next can be prepared while the substrate is being processed with the aqueous solution applied to it. This shortens the time of replenishing the aqueous solution of phosphoric acid, and ultimately raises the efficiency of the etching process.

In each of the embodiments described above, the aqueous solution of phosphoric acid is applied to the substrate on condition that it has the prescribed silica concentration and the predetermined temperature. Nonetheless, it may be applied to the substrate if it has only the prescribed silica concentration.

In the second embodiment, the fresh aqueous solution of phosphoric acid is supplied from the sub-tank 25 to the tank 21, thus replenishing the solution, in accordance with the silica concentration and temperature of the solution in the tank 21. Instead, the solution may be replenished in accordance with the silica concentration only. Moreover, two sub-tanks may be used.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A wet etching apparatus designed to process a substrate on which at least a nitride film and an oxide film are formed, the apparatus comprising:
a reservoir unit for storing an aqueous solution of phosphoric acid;
an additive reservoir unit for storing a silica additive;
a concentration detecting unit configured to detect the silica concentration in the aqueous solution of phosphoric acid stored in the reservoir unit;
an additive supplying unit configured to supply the silica additive from the additive reservoir unit to the reservoir unit if the silica concentration in the aqueous solution of phosphoric acid, detected by the concentration detecting unit, is lower than a prescribed value; and
a processing unit configured to process the substrate with the aqueous solution of phosphoric acid stored in the reservoir unit.

2. The wet etching apparatus according to claim 1, further comprising a recovery unit configured to recover the aqueous solution of phosphoric acid from the processing unit and supplying the aqueous solution back to the reservoir unit.

3. The wet etching apparatus according to claim 1, wherein the aqueous solution of phosphoric acid is supplied from the reservoir unit to the processing unit on condition that the silica concentration in the aqueous solution of phosphoric acid, detected by the detecting unit, is of the prescribed value.

4. The wet etching apparatus according to claim 1, wherein the silica additive is colloidal silica.

5. The wet etching apparatus according to claim 2, wherein the silica additive is colloidal silica.

6. The wet etching apparatus according to claim 3, wherein the silica additive is colloidal silica.

7. The wet etching apparatus according to claim 1, wherein the additive supplying unit has a sub-tank arranged between the additive reservoir unit and the reservoir unit, and the aqueous solution of phosphoric acid is supplied to the sub-tank from an aqueous solution supplying unit containing the aqueous solution of phosphoric acid.

8. The wet etching apparatus according to claim 3, which further comprises a temperature detecting unit configured to detect the temperature of the aqueous solution of phosphoric acid, stored in the reservoir unit, and in which the aqueous solution of phosphoric acid is supplied from the reservoir unit to the processing unit on condition that the temperature of the aqueous solution, detected by the temperature detecting unit, is of a preset value.

9. The wet etching apparatus according to claim 1, wherein a circulation unit is provided in the reservoir unit and configured to circulate the aqueous solution of phosphoric acid and heat the aqueous solution of phosphoric, while circulating the same.
